(19) United States
(12) Patent Application Publication
(10) Pub. No.: US 2010/0013079 A1
(43) Pub. Date: Jan. 21, 2010

(54) PACKAGE SUBSTRATE, SEMICONDUCTOR PACKAGE HAVING A PACKAGE SUBSTRATE

(75) Inventors: In-Sik Cho, Seongnam-si (KR); Yong-Kwan Lee, Yongin-si (KR); Cheol-Joon Yoo, Suwon-si (KR)

Correspondence Address: STANZIONE & KIM, LLP, 919 18TH STREET, N.W., SUITE 440, WASHINGTON, DC, 20006, US

(73) Assignee: Samsung Electronics Co., Ltd, Suwon-si (KR)

(21) Appl. No.: 12/504,209

(22) Filed: Jul. 16, 2009

(30) Foreign Application Priority Data
Jul. 21, 2008 (KR) 2008-70532

(51) Int. Cl. H01L 23/28

(52) U.S. Cl. 257/690; 257/787; 257/E23.116

(57) ABSTRACT

A package substrate may include an insulating substrate, a circuit pattern and a mold gate pattern. The insulating pattern may have a mold gate region through which a molding member may pass. The circuit pattern may be formed on the insulating substrate. The mold gate pattern may be formed on the mold gate region of the insulating substrate. The mold gate pattern may include a polymer having relatively strong adhesion strength with respect to the insulating substrate and relatively weak adhesion strength with respect to the molding member. Thus, costs of the package substrate and the semiconductor package may be decreased.

### CROSS-REFERENCE TO RELATED APPLICATIONS

This application claims priority under 35 USC §119 to Korean Patent Application No. 2008-70532, filed on Jul. 21, 2008 in the Korean Intellectual Property Office (KIPO), the contents of which are herein incorporated by reference in their entirety.

### BACKGROUND

1. Field of the Invention

Example embodiments relate to a package substrate, a method of manufacturing a package substrate, a semiconductor package having a package substrate, and a method of manufacturing a semiconductor package. More particularly, example embodiments relate to a package substrate having a mold gate region through which a molding member may pass, a method of manufacturing the package substrate, a semiconductor package having the package substrate, and a method of manufacturing the semiconductor package.

2. Description of the Related Art

Generally, various semiconductor fabrication processes may be performed on a semiconductor substrate to form a plurality of semiconductor chips. In order to mount the semiconductor chips on a printed circuit board (PCB), a packaging process may be performed on the semiconductor chips to form semiconductor packages.

The semiconductor package may include a semiconductor chip, a package substrate on which the semiconductor chip may be mounted, conductive wires configured to electrically connecting the semiconductor chip with the package substrate, and a molding member formed on the package substrate to cover the conductive wires.

The molding member may be formed using a mold die that may have two cavities configured to receive the two package substrates. A molding material may be supplied into the cavities through mold gate regions of the package substrates to form the molding member.

After forming the molding member, a cull of the molding member may remain between the package substrates. The cull of the molding member may be unnecessary to form the semiconductor package. Thus, the cull of the molding member may be removed by a degating process (a process of detaching the cull of the molding member from the molding member itself).

In order to readily remove the cull, mold gate patterns may be formed in the mold gate regions of the package substrates. Here, the mold gate pattern may have proper adhesion strength between the package substrates and the molding member.

However, the conventional mold gate pattern may include gold, and since the gold may be expensive, this may cause high prices of the package substrate and the semiconductor package. Further, because the gold mold gate pattern may be formed by a plating process, this may cause increasingly higher prices of the package substrate and the semiconductor package.

### SUMMARY

Example embodiments provide a package substrate that may be manufactured at a low cost.

Example embodiments also provide a method of manufacturing the above-mentioned package substrate.

Example embodiments also provide a semiconductor package having the above-mentioned package substrate.

Example embodiments also provide a method of manufacturing the above-mentioned semiconductor package.

Additional features and utilities of the present general inventive concept will be set forth in part in the description which follows and, in part, will be obvious from the description, or may be learned by practice of the general inventive concept.

Some exemplary embodiments of the present general inventive concept provide a package substrate including an insulating substrate, a circuit pattern and a mold gate pattern. The insulating pattern may have a mold gate region through which a molding member may pass. The circuit pattern may be formed on the insulating substrate. The mold gate pattern may be formed on the mold gate region of the insulating substrate. The mold gate pattern may include a polymer having relatively strong adhesion strength with respect to the insulating substrate and a relatively weak adhesion strength with respect to the molding member.

In some example embodiments, the mold gate pattern may include a thermoplastic material or a thermosetting material having a thermal resistance.

In some example embodiments, the circuit pattern may be arranged in a central portion of the insulating substrate. The mold gate region may be positioned in an edge portion of the insulating substrate.

In some example embodiments, the circuit pattern may include a plurality of pattern arrays on which a group of semiconductor packages may be mounted.

Some exemplary embodiments of the present general inventive concept also provide a method of manufacturing a package substrate. In the method of manufacturing the package substrate, a circuit pattern may be formed on an insulating substrate having a mold gate region through which a molding member may pass. A mold gate pattern may be formed on the mold gate region of the insulating substrate. The mold gate pattern may include a polymer having relatively strong adhesion strength with respect to the insulating substrate and a relatively weak adhesion strength with respect to the molding member.

In some example embodiments, forming the mold gate pattern may include forming a photosensitive resist film on the insulating substrate, patterning the photosensitive resist film to form a photosensitive resist pattern configured to expose the circuit pattern and the mold gate region, and filling the mold gate region exposed through the photosensitive resist pattern with the mold gate pattern.

In some example embodiments, filling the mold gate region with the mold gate pattern may be performed by a spray coating process, an ink jet printing process, a roll coating process, a screen/stencil printing process, etc.

Some exemplary embodiments of the present general inventive concept also provide a semiconductor package. The semiconductor package may include a package substrate, a semiconductor chip, conductive connecting members and a molding member. The package substrate may include an insulating substrate, a circuit pattern and a mold gate pattern. The insulating pattern may have a mold gate region. The circuit pattern may be formed on the insulating substrate. The mold gate pattern may be formed on the mold gate region of the insulating substrate. The mold gate pattern may include a polymer having relatively strong adhesion strength with respect to the insulating substrate and a relatively weak adhesion strength with respect to the molding member. The semiconductor chip may be mounted on the insulating substrate. The conductive connecting members may be electrically connected between the semiconductor chip and the circuit pattern. The molding member may be formed on the package substrate and the semiconductor chip to cover the conductive connecting members.

In some example embodiments, the conductive connecting members may include conductive wires.

Some exemplary embodiments of the present general inventive concept also provide a method of manufacturing a semiconductor package. In the method of manufacturing the semiconductor package, two package substrates may be prepared. Each of the package substrate may include an insulating substrate having a mold gate region, a circuit pattern formed on the insulating substrate, and a mold gate pattern including a polymer material formed on the mold gate region of the insulating substrate. A semiconductor chip may be mounted on the insulating substrate. The semiconductor chip and the circuit pattern may be electrically connected with each other using conductive connecting members. A molding member may be formed on the package substrate and the semiconductor chip to cover the conductive connecting members. A cull of the molding member, which may be located between the package substrates, may be detached.

In some example embodiments, forming the molding member may include arranging the package substrates in two cavities of a mold die, and supplying a molding material into the cavities through the mold gate regions.

In some example embodiments, forming the molding member may further include detaching the package substrates having the molding member from the mold die.

In some example embodiments, forming the molding member may further include transferring the detached package substrates to a lot where the degating process may be performed.

According to some example embodiments, the mold gate pattern may include the cheap polymer material, so that costs of the package substrate and the semiconductor package may be decreased. Further, the mold gate pattern may provide proper adhesion strength between the insulating substrate and the molding member, so that the cull of the molding member may be readily degated (detached).

Furthermore, because the mold gate pattern including the inexpensive polymer material may be formed by a simple coating process, the costs of the package substrate and the semiconductor package may be decreased and/or reduced to a minimum.

### BRIEF DESCRIPTION OF THE DRAWINGS

Example embodiments will be more clearly understood from the following detailed description taken in conjunction with the accompanying drawings. FIGS. 1 to 14 represent non-limiting, example embodiments as described herein.

These and/or other features and utilities of the present general inventive concept will become apparent and more readily appreciated from the following description of the embodiments, taken in conjunction with the accompanying drawings of which:

FIG. 1 is a plan view illustrating a package substrate in accordance with some example embodiments;

FIGS. 2 to 5 are cross-sectional views illustrating a method of manufacturing the package substrate in FIG. 1;

FIG. 6 is a plan view illustrating a semiconductor package in accordance with some example embodiments;

FIG. 7 is a cross-sectional view taken along a line VII-VII′ in FIG. 6;

FIGS. 8 to 13 are cross-sectional views and a plan view illustrating a method of manufacturing the semiconductor package in FIGS. 6 and 7; and

FIG. 14 is a plan view illustrating a mold die used to mold the semiconductor package.

### DETAILED DESCRIPTION OF THE EMBODIMENTS

Various example embodiments will be described more fully hereinafter with reference to the accompanying drawings, in which some example embodiments are shown. The present general inventive concept may, however, be embodied in many different forms and should not be construed as limited to the example embodiments set forth herein. Rather, these example embodiments are provided so that this disclosure will be thorough and complete, and will fully convey the scope of the present general inventive concept to those skilled in the art. In the drawings, the sizes and relative sizes of layers and regions may be exaggerated for clarity.

It will be understood that when an element or layer is referred to as being “on,” “connected to” or “coupled to” another element or layer, it can be directly on, connected or coupled to the other element or layer or intervening elements or layers may be present. In contrast, when an element is referred to as being “directly on,” “directly connected to” or “directly coupled to” another element or layer, there are no intervening elements or layers present. Like numerals refer to like elements throughout. As used herein, the term “and/or” includes any and all combinations of one or more of the associated listed items.

It will be understood that, although the terms first, second, third etc. may be used herein to describe various elements, components, regions, layers and/or sections, these elements, components, regions, layers and/or sections should not be limited by these terms. These terms are only used to distinguish one element, component, region, layer or section from another region, layer or section. Thus, a first element, component, region, layer or section discussed below could be termed a second element, component, region, layer or section without departing from the teachings of the present general inventive concept.

Spatially relative terms, such as “beneath,” “below,” “lower,” “above,” “upper” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the exemplary term “below” can encompass both an orientation of above and below. The device may be otherwise oriented (rotated 90 degrees or at other orientations) and the spatially relative descriptors used herein interpreted accordingly.

The terminology used herein is for the purpose of describing particular example embodiments only and is not intended to be limiting of the present general inventive concept. As used herein, the singular forms “a,” “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

Example embodiments are described herein with reference to cross-sectional illustrations that are schematic illustrations of idealized example embodiments (and intermediate structures). As such, variations from the shapes of the illustrations as a result, for example, of manufacturing techniques and/or tolerances, are to be expected. Thus, example embodiments should not be construed as limited to the particular shapes of regions illustrated herein but are to include deviations in shapes that result, for example, from manufacturing. For example, an implanted region illustrated as a rectangle will, typically, have rounded or curved features and/or a gradient of implant concentration at its edges rather than a binary change from implanted to non-implanted region. Likewise, a buried region formed by implantation may result in some implantation in the region between the buried region and the surface through which the implantation takes place. Thus, the regions illustrated in the figures are schematic in nature and their shapes are not intended to illustrate the actual shape of a region of a device and are not intended to limit the scope of the present invention.

Unless otherwise defined, all terms (including technical and scientific terms) used herein have the same meaning as commonly understood by one of ordinary skill in the art to which this invention belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

Hereinafter, example embodiments will be explained in detail with reference to the accompanying drawings.

Package Substrate

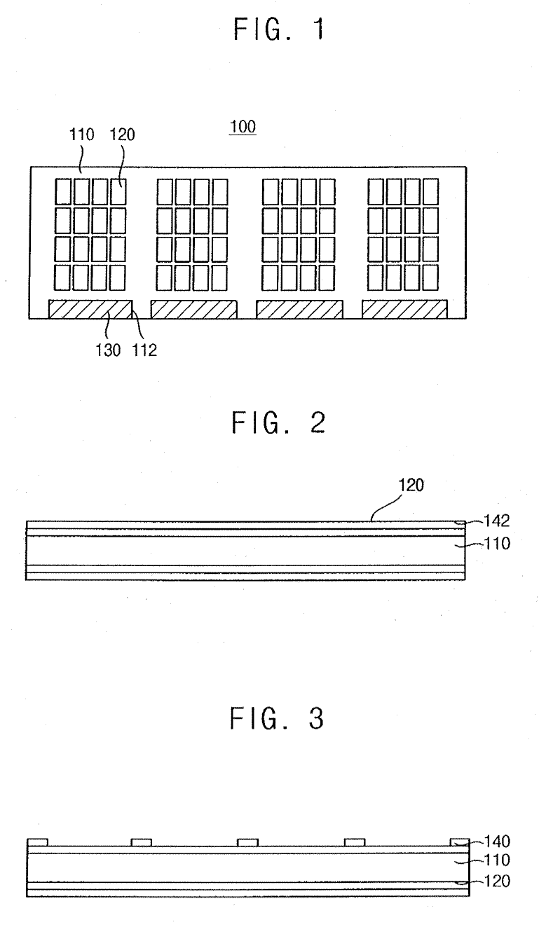

FIG. 1 is a plan view illustrating a package substrate in accordance with some example embodiments.

Referring to FIG. 1, the package substrate 100 of this example embodiment may include an insulating substrate 110, circuit patterns 120 and mold gate patterns 130.

The insulating substrate 110 may have a rectangular plan shape. The insulating substrate 110 may have a plurality of mold gate regions 112. During a molding process to mold a semiconductor package, a molding material may be introduced into a space over the insulating substrate 110 through the mold gate regions 112. Here, the molding process may be simultaneously performed on the two package substrates 100. Particularly, the package substrates 100 may be loaded into two cavities of a mold die, respectively. The molding material may be introduced into the spaces of the package substrates 100 through the mold gate regions 112 to form a molding member configured to cover the semiconductor substrates 100 and conductive wires. Thus, a cull of the molding member configured to connect the package substrates 100 with each other may be formed between the package substrates 100. The package substrates 100 may then be detached from the mold die. Here, because there may be no use for, or benefit of the cull of the molding member, the package substrates 100 may be transferred to a lot where a degating (detaching of the cull) process is performed. The degating process may be performed on the package substrates 100 to remove the cull of the molding member. In some example embodiments, the mold gate regions 112 may be linearly arranged on an edge portion of an upper surface of the insulating substrate 110.

The circuit patterns 120 may be arranged on a central portion of the insulating substrate 110 and the circuit patterns 120 may include a plurality of pattern arrays, as illustrated, for example, in FIG. 1. A group of semiconductor packages may be mounted on the pattern arrays. In some example embodiments, the circuit patterns 120 may include a metal such as copper, aluminum, etc.

The mold gate patterns 130 may be arranged in the mold gate regions 112 of the insulating substrate 110. Here, because the mold gate regions 112 may be positioned on the edge portion of the upper surface of the insulating substrate 110, the mold gate patterns 130 may be linearly arranged on the edge portion of the upper surface of the insulating substrate 110.

In some example embodiments, the mold gate patterns 130 may provide proper adhesion strength between the insulating substrate 110 and the molding member. Particularly, when the adhesion strength between the insulating substrate 110 and the molding member is too high, the cull of the molding member may not be completely removed during the detaching process. In contrast, when the adhesion strength between the insulating substrate 110 and the molding member is too low, the cull of the molding member may be prematurely removed in the detaching process. Such a prematurely removed cull of the molding member may cause a malfunction of a transferring unit to transfer the package substrate 100 to the lot. Thus, in order to maintain the cull of the molding member connected with the insulating substrate 110 in the detaching process and the transferring process, and also readily separate the cull of the molding member from the insulating substrate 110 in the detaching process, the mold gate patterns 130 may include a material having proper adhesion strength between the insulating substrate 110 and the molding member. Therefore, the material of the mold gate patterns 130 may have relatively strong adhesion strength with respect to the insulating substrate 110 and relatively weak adhesion strength with respect to the molding member. Particularly, the material of the mold gate patterns 130 may have a heat resistance to allow the mold gate patterns 130 to be stabilized physically and chemically at a molding temperature of no less than about 180°.

In some example embodiments, the mold gate patterns 130 having the above-mentioned characteristics may include a polymer material. Examples of the polymer material may include a thermoplastic resin or a thermosetting resin. Here, because a cost of a polymer material may be very low as compared to that of gold, a cost of manufacturing the package substrate 100 may be remarkably reduced. Further, the polymer material may be formed by a simple and inexpensive coating process such as a spray coating process, an ink jet printing process, a roll coating process, a screen/stencil printing process, etc. As a result, the cost of manufacturing the package substrate 100 may be greatly reduced.

According to this example embodiment, the mold gate pattern may include the inexpensive polymer material. Therefore, a price of the package substrate may be greatly decreased.

Method of Manufacturing a Package Substrate

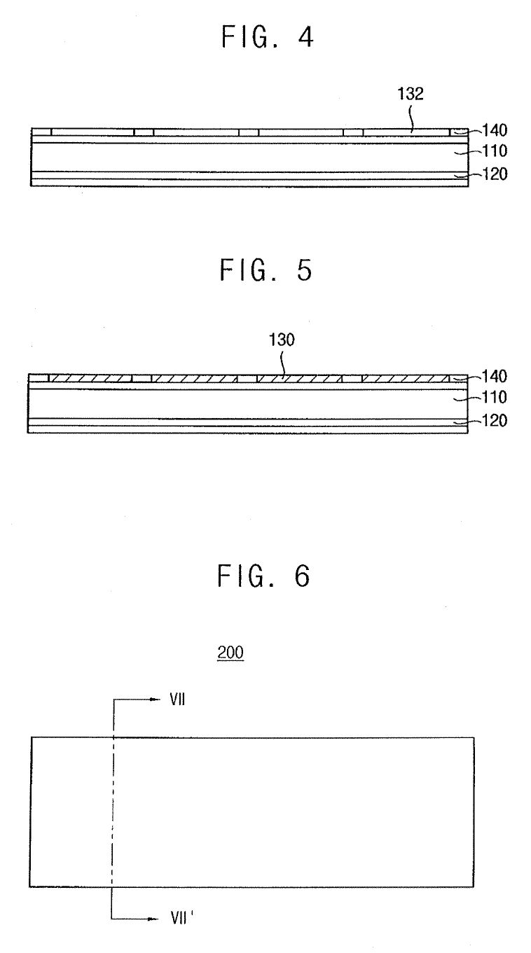

FIGS. 2 to 5 are cross-sectional views illustrating a method of manufacturing the package substrate in FIG. 1.

Referring to FIG. 2, the circuit patterns 120 may be formed on the insulating substrate 110 having the mold gate regions 112. In some example embodiments, the circuit patterns 120 may include metal such as copper, aluminum, etc. Further, the circuit patterns 120 may be formed by a sputtering process. A photosensitive resist film 142 may then be formed on the insulating substrate 110 to cover the circuit patterns 120 with the photosensitive resist film 142.

Referring to FIG. 3, the photosensitive resist film 142 may be patterned to form a photosensitive resist pattern 140 configured to expose the circuit patterns 120 and the mold gate regions 112.

Referring to FIG. 4, the mold gate regions 112 (see FIG. 1) exposed through the photosensitive resist pattern 140 may be filled with the mold gate patterns 130 including the polymer material. The mold gate patterns 130 may be formed by a spray coating process, an ink jet printing process, a roll coating process, a screen/stencil printing process, etc.

Referring to FIG. 5, the mold gate patterns 130 may be planarized to complete the package substrate 100 in FIG. 1. In some example embodiments, the mold gate patterns 130 may have an upper surface substantially coplanar with or lower than that of the photosensitive resist pattern 140. Further, the photosensitive resist pattern 140 may have a thickness of about 20 μm to about 25 μm. Thus, the mold gate patterns 130 may have a thickness of about 20 μm to about 25 μm.

Semiconductor Package

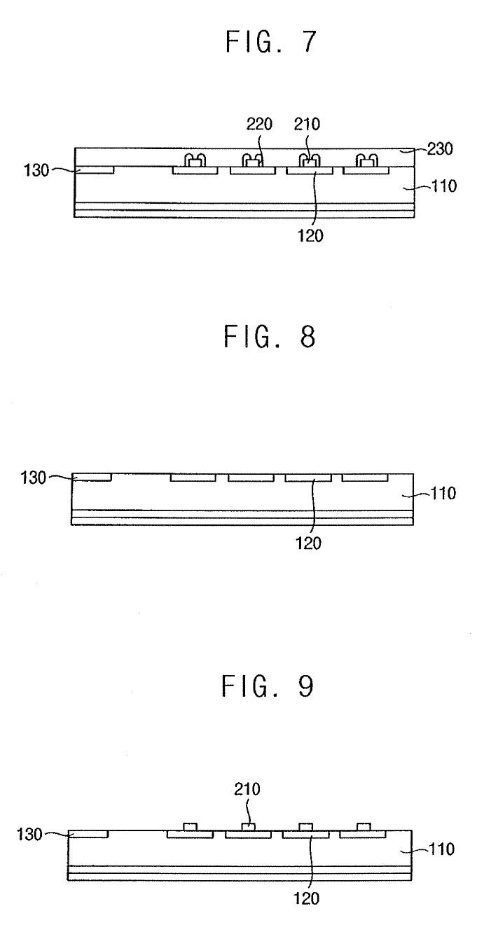

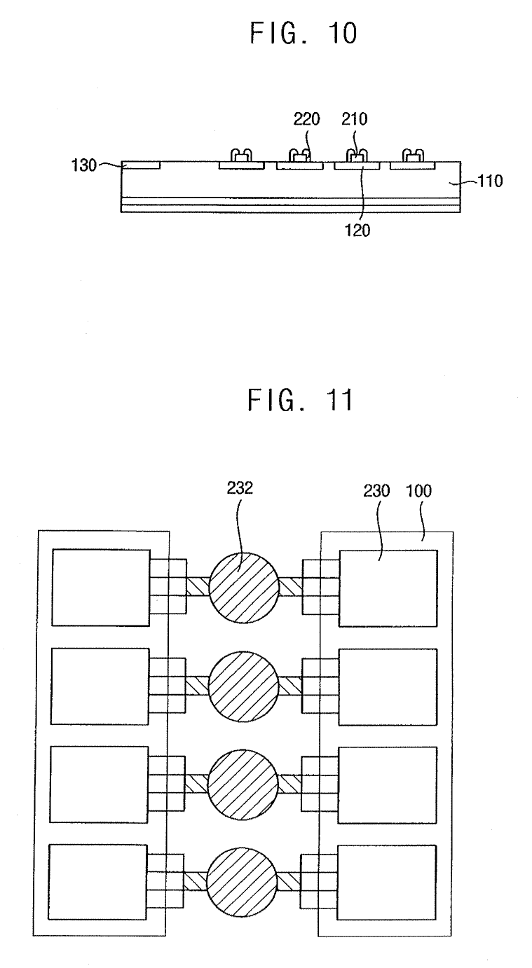

FIG. 6 is a plan view illustrating a semiconductor package in accordance with some example embodiments, and FIG. 7 is a cross-sectional view taken along a line VII-VII′ in FIG. 6.

Referring to FIGS. 6 and 7, the semiconductor package 200 of this example embodiment may include semiconductor chips 210, the package substrate 100, conductive connecting members 220 and a molding member 230.

Here, the package substrate 100 may include elements substantially the same as those of the package substrate in FIG. 1. Thus, the same reference numerals refer to the same elements, and any further illustrations with respect to the same elements are omitted herein for brevity of the detailed description.

The semiconductor chips 210 may be mounted on the insulating substrate 110 of the package substrate 100. Each of the semiconductor chips 210 may have bonding pads (not shown).

The conductive connecting members 220 may connect the bonding pads of the semiconductor chips 210 with the circuit patterns 120 of the package substrate 100. In some example embodiments, the conductive connecting members 220 may include a conductive wire, such as a gold wire.

The molding member 230 may be formed over the package substrate 100 and the semiconductor chips 210 to cover the conductive connecting members 220. The molding member 230 can protect the conductive connecting members 220 from external impacts to prevent damages of the conductive connecting members 220. In some example embodiments, the molding member 230 may include an epoxy molding compound (EMC).

Method of Manufacturing a Semiconductor Package

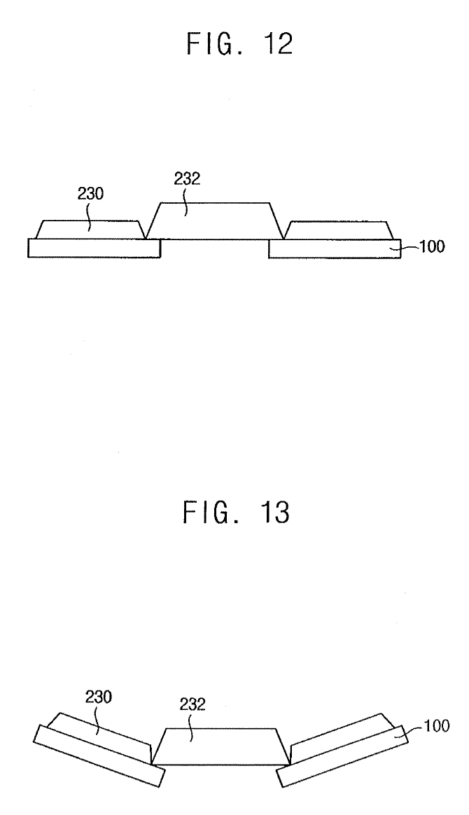

FIGS. 8 to 13 are cross-sectional views and a plan view illustrating a method of manufacturing the semiconductor package in FIGS. 6 and 7, and FIG. 14 is a plan view illustrating a mold die used to mold the semiconductor package.

Referring to FIG. 8, the two package substrates 100 may be prepared. In some example embodiments, each of the package substrates 100 may include the insulating substrate 110 having the mold gate regions 112, the circuit patterns 120 formed on the insulating substrate 110, and the mold gate patterns 130 formed in the mold gate regions 112 of the insulating substrate 110. The mold gate patterns 130 may include a polymer material. Here, processes to form the package substrates 100 may be substantially the same as those illustrated with reference to FIGS. 2 to 5. Thus, any further illustrations with respect to the same processes are omitted herein for brevity of the detailed description.

Referring to FIG. 9, the semiconductor chips 210 may be mounted on the insulating substrate 110 of the package substrate 100. In some example embodiments, the semiconductor chips 210 may be attached to the insulating substrate 110 using an adhesive layer (not shown).

Referring to FIG. 10, the bonding pads of the semiconductor chips 210 may be electrically connected with the circuit patterns 120 of the package substrate 100 using the conductive connecting members 220 such as the conductive wires. Thus, the semiconductor chips 210 and the package substrate 100 may be electrically connected with each other via the conductive connecting members 220.

Referring to FIGS. 11 and 12, the molding member 230 may be formed on the semiconductor chips 210 and the package substrate 100 to cover the conductive connecting members 220 with the molding member 230. Here, the molding member 230 may have the cull 232 configured to connect the package substrates 100 with each other.

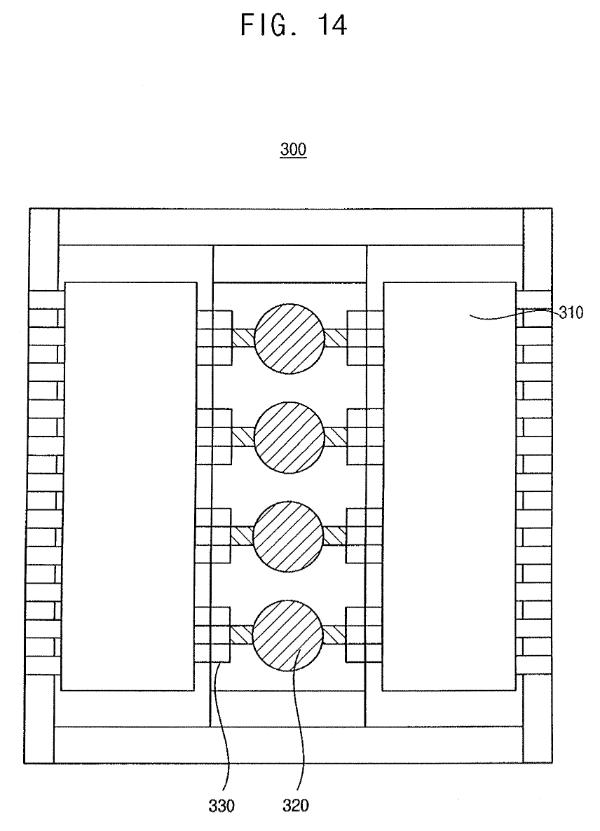

In some example embodiments, the molding process may use a mold die 300 in FIG. 14. The mold die 300 may have two mold cavities 310 configured to receive the two package substrates 100. A molding material may be injected into the mold cavities through the mold gate regions 112. The mold cavities 310 may be in fluidic communication with a cull cavity 320, which may be located at a central portion of the mold die 300, through runners 330.

When the molding material is introduced into the cull cavity 320, the molding material may be injected into the mold cavities 310 through the runners 330 and the mold gate regions 112. The molding material may then be cured to form the molding member 230 configured to cover the connecting conductive members 220.

The two package substrates 100 having the molding member 230 may then be detached from the mold die 300. As shown in FIGS. 11 and 12, the molding member 230 may have the cured cull 232 in the cull cavity 320. Thus, the two package substrates 100 may be connected with each other via the cull 232 of the molding member 230.

In some example embodiments, because the mold gate patterns 130 may include the polymer material, the mold gate patterns 130 may have strong adhesions strength with respect to the insulating substrate 110. Therefore, when performing the detaching process, the cull 232 of the molding member 230 may not be separated from the molding member 230. As a result, the transferring unit to transfer the package substrates 100 to the detaching lot may not be out of order due to the cull being separated from the molding member 230.

Referring to FIG. 13, the package substrates 100 connected with each other via the cull 232 may be transferred to the detaching lot using the transferring unit.

In some example embodiments, the mold gate patterns 130 may have strong adhesion strength with respect to the insulating substrate 110. Thus, during the transferring process, the cull 232 of the molding member 230 can be prevented from being separated from the molding member 230.

The cull 232 of the molding member 230 may then be detached to remove the cull 232 from the package substrates 100, thereby completing the semiconductor package 200 in FIG. 7.

In some example embodiments, the mold gate patterns 130 may have weak adhesion strength with respect to the molding member 230. Therefore, the cull 232 may be readily removed from the molding member 230 in the detaching process. As a result, the cull 232 of the molding member 230 may not remain after the detaching process, so that the cull 232 may not have influences on later processes.

According to this example embodiment, the mold gate pattern including the polymer may have the strong adhesion strength with respect to the insulating substrate and the weak adhesion strength with respect to the molding member. Thus, the cull may not be separated from the insulating substrate in the detaching process. Further, the cull may be easily separated from the molding member in the detaching process.

Here, in some example embodiments, the semiconductor package including the conductive connecting members such as the conductive wires may be exemplarily explained. Alternatively, example embodiments may be applied to other semiconductor packages including the molding member.

According to some example embodiments, the mold gate pattern may include an inexpensive polymer material, so that costs of the package substrate and the semiconductor package may be decreased. Further, the mold gate pattern may provide proper adhesion strength between the insulating substrate and the molding member, so that the cull of the molding member may be readily detached.

Furthermore, because the mold gate pattern including the cheap polymer material may be formed by a simple coating process, the costs of the package substrate and the semiconductor package may be more decreased.

The foregoing is illustrative of example embodiments and is not to be construed as limiting thereof. Although a few example embodiments have been described, those skilled in the art will readily appreciate that many modifications are possible in the example embodiments without materially departing from the novel teachings and advantages of the present invention. Accordingly, all such modifications are intended to be included within the scope of the present invention as defined in the claims. In the claims, means-plus-function clauses are intended to cover the structures described herein as performing the recited function and not only structural equivalents but also equivalent structures. Therefore, it is to be understood that the foregoing is illustrative of various example embodiments and is not to be construed as limited to the specific example embodiments disclosed, and that modifications to the disclosed example embodiments, as well as other example embodiments, are intended to be included within the scope of the appended claims.

Although a few embodiments of the present general inventive concept have been shown and described, it will be appreciated by those skilled in the art that changes may be made in these embodiments without departing from the principles and spirit of the general inventive concept, the scope of which is defined in the appended claims and their equivalents.

1. A package substrate comprising:
an insulating substrate having a mold gate region through which a molding member passes;
a circuit pattern formed on the insulating substrate; and
a mold gate pattern formed in the mold gate region of the insulating substrate, the mold gate pattern including a polymer material that has relatively strong adhesion strength with respect to the insulating substrate and relatively weak adhesion strength with respect to the molding member.

2. The package substrate of claim 1, wherein the mold gate pattern comprises a thermoplastic resin or a thermosetting resin having a heat resistance.

3. The package substrate chip of claim 1, wherein the circuit pattern is arranged on a central portion of the insulating substrate, and the mold gate region is arranged on an edge portion of the insulating substrate.

4. The package substrate of claim 1, wherein the circuit pattern comprises a plurality of pattern arrays on which a group of semiconductor packages are mounted.

5-7. (canceled)

8. A semiconductor package comprising:
a package substrate including an insulating substrate that has a mold gate region, a circuit pattern formed on the insulating substrate, and a mold gate pattern formed in the mold gate region of the insulating substrate;
a semiconductor chip mounted on the insulating substrate;
conductive connecting members configured to electrically connect the semiconductor chip with the circuit pattern; and
a molding member formed on the package substrate and the semiconductor chip to cover the conductive connection members,
wherein the mold gate pattern includes a polymer material having relatively strong adhesion strength with respect to the insulating substrate and relatively weak adhesion strength with respect to the molding member.

9. The semiconductor package of claim 8, wherein the conductive connection members comprise conductive wires.

10-13. (canceled)

14. A package substrate comprising:
an insulating substrate having mold gate regions to receive a molding member therein; and
mold gate patterns formed in the mold gate regions and including a polymer material which adheres stronger to the insulating substrate than the molding member.

15. The package substrate of claim 14, further comprising:
circuit patterns formed in the insulating substrate to connect with semiconductor chips via conductive connecting members disposed within the molding member.

16. The package substrate of claim 14, wherein the material of the mold gate patterns have a heat resistance to allow the mold gate patterns to be stabilized physically and chemically at a molding temperature of no less than 180 degrees.

17. The package substrate of claim 14, wherein the mold gate patterns include either a thermoplastic resin or a thermosetting resin.

18-20. (canceled)
